(19) United States
(12) Patent Application Publication
(10) Pub. No.: US 2003/0012066 A1
(43) Pub. Date: Jan. 16, 2003

(54) Memory and method for replacing defective memory cells in the same

(76) Inventor: Peter Poechmueller, Colchester, VT (US)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/195,753

(22) Filed: Jul. 15, 2002

(30) Foreign Application Priority Data
Jul. 13, 2001 (DE) 101 34 090.7

(51) Int. Cl. G11C 29/00

(52) U.S. Cl. 365/200

(57) ABSTRACT

A memory wherein defective memory cells may be replaced includes a first memory region having at least one memory cell with an associated bit line, a second memory region having at least one memory cell with an associated bit line and a world line associated at least with the memory cell of the first memory region and the memory cell of the second memory region. Further, at least one redundant memory cell having an associated bit line and a means is provided to selectively couple the bit line of the redundant memory cell to the bit line of the memory cell of the first memory region or to the bit line of the memory cell of the second memory region in order to replace a defective memory cell in the first memory region or a defective memory cell in the second memory region.

### FIELD OF THE INVENTION

The present invention relates to a memory and a method for replacing defective memory cells in the same and in particular to a memory and a method wherein redundant memory cells are provided in order to replace defective memory cells.

### BACKGROUND OF THE INVENTION AND PRIOR ART

Today's semiconductor devices, like e.g. DRAM semiconductor devices (DRAM=Dynamic Random Access Memory) are increasingly difficult to produce. The reason for this mainly is that more and more effort is necessary in order to realise defectless memory cells within the semiconductor devices. Despite the effort used in the production of semiconductor devices it is not possible to produce fully defectless semiconductor devices. For this reason today's DRAM semiconductor devices comprise a massive redundancy, i.e. replacement memory cells are provided in the form of redundant lines and/or redundant columns in order to replace defective memory cells with the same if necessary.

If a memory cell is classified as defective within a semiconductor device either a line containing this defective memory cell or a column containing this defective memory cell is replaced by activating one of the provided redundant memory cells or rather a provided redundant line and/or a provided redundant column having corresponding memory cells, so that when addressing the original memory cell recognised as defective the same is not accessed but the respective provided redundant line and/or the redundant column is activated, depending on a selected replacement scheme. This activation of the redundant cells is usually done via programming by provided laser structures or electrical “fuse” structures wherein a metal trace is e.g. separated by laser bombardment.

In FIG. 1 a schematic illustration of a first prior memory configuration is shown comprising several memory regions each having redundant bit lines associated with them. In FIG. 1 a memory 100 is shown divided into a memory area A and a memory area B, as is indicated by the dashed line 102.

In the following description similar or near similar elements are designated with same reference numerals in the respective memory regions A and B, however additionally comprise the character “A” or “B” depending on their affiliation.

The first memory region A includes a memory cell 104A and a redundant memory cell 106A. The memory cell 104A has a bit line BL_{1A} associated with the same and a redundant memory cell 106A has a bit line BL_{2A} associated with it. The bit lines BL_{1A} and BL_{2A} are connected to a local data bus 108A which is connected to a global data bus or an output data bus 112A via an amplifier 110A.

The second memory region B includes a memory cell 104B and a redundant memory cell 106B. A bit line BL_{1B} is associated with the memory cell 104B and a bit line BL_{2B} is associated with the redundant memory cell 106B. The bit lines BL_{1B} and BL_{2B} are connected to a local data bus 108B which is connected to a global data bus or an output data bus 112B via an amplifier 110B. As the areas A and B are accessed simultaneously, two output buses 112A and 112B are provided.

The memory further includes a word line WL associated with the memory cells 104A, 104B, 106A, and 106B.

Each memory cell contains one bit, so that when reading out the memory cells one bit is comprised on the local data buses 108A and 108B, so that their width is 1 bit, as it was indicated. Accordingly, the width of the data buses 112A and/or 112B is 1 bit.

If it is determined that the memory cells 104A and 104B are fully functional, i.e. not defective, the bits stored in the memory cells 104A or 104B are read out to the output data buses 112A and 112B via said data buses 108A and 108B when activating the word line WL and activating the bit lines BL_{1A} and/or BL_{2B}. In the case of a memory cell 104A in the first memory region A being defective a respective activation of the redundant memory cell 106A results. In this case the memory cell 106A is used instead of the memory cell 104A in an activation and its memory content is output onto to the data bus 108A and further onto the data bus 112A. Accordingly, a replacement of the defective memory cell in the second memory region B results.

The disadvantage of the memory configuration described in FIG. 1 is that it only enables a repair and/or a replacement of defective memory cells using a redundant memory cell in one of the memory regions A and B as otherwise data conflicts might occur. The redundant memory cell 106B may e.g. not be used to repair the memory cell 104A as the data would not appear on the output data bus 112A.

In FIG. 2 a second prior memory configuration is illustrated wherein several memory cells are selected by so-called column selection lines and read out simultaneously in the memory, wherein individual memory areas are associated with redundant column selection lines.

The memory configuration illustrated in FIG. 2 includes a memory 200 divided into a first memory region A and a second memory region B, as it is indicated by the dashed line 202, similar to FIG. 1.

The memory 200 includes a plurality of word lines WL, wherein only one word line WL is shown for reasons of clarity. The memory region A includes a plurality of selection lines CSL (CSL=Column Select Line) wherein only three such column select lines are shown in each of the areas A and B in FIG. 2 for reasons of clarity.

The memory region A includes a first column select line CSL_{1A}. Further, two redundant column select lines CSL_{2A} and CSL_{3A} are associated with the memory region A.

One portion is designated with the reference numeral 204A, which illustrates the configuration using said column select lines. According to the example described in FIG. 2 a plurality of bit lines, four bit lines in the illustrated example, are associated with each column select line. Memory cells designated by rectangles are activated and their content is read out in the portion 204A via an activation of said word line WL and said selection line CSL_{1A}.

If it is determined now that one of the bit lines selected by a common column select line has a defective memory cell associated with it, as it is exemplary designated at “X” in FIG. 2, a respective replacement of the column select line with the defective memory cell is carried out using the redundant column select line CSL_{2A}. The structure of the replacement column select lines is identical with the structure of the column select lines (see portion 204A), i.e. it includes a plurality of bit lines BL and a plurality of memory cells.

The second memory region B also includes a plurality of column select lines, wherein for reasons of clarity only one column select line CSL_{1B} is shown exemplary. Similar to the memory region A also the memory region B has a first replacement column select line CSL_{2B} and a second replacement column select line CSL_{3B} associated with it. The portion 204B shows the column select line CSL_{3B} which has a plurality of bit lines BL associated with it, four bit lines in the shown example. The memory cells designated by rectangles in portion 204B are activated by an activation of the word line WL and the select line CSL_{3B} and their content is read out.

The portion 204C schematically shows a possible arrangement of defective memory cells in the memory area B, which are corrected by the two replacement column select. lines CSL₂B and CSL₃B, as it is indicated by the arrows.

The column select lines of the memory region A are connected to a first local data bus 208A which comprises a width of four bit due to the configuration shown in FIG. 2, as it is shown schematically. Via a detection amplifier 210A the data bus 208A is connected to a first portion 212A of an output data bus via a global data bus 212.

Accordingly, the column select lines of the memory area B are connected to a local data bus 208B which is four bit wide and is in turn connected to a second portion 212B of the global data bus 212 via a detection amplifier 210B.

The configuration illustrated in FIG. 2 includes the memory cell field 200 comprising word lines WL and bit lines BL. After activating a word line WL and the associated bit line BL a predetermined number of bits determined by the column address is read out to the local data buses 208A and/or 208B. Herefore the “normal” column select lines CSL_{1A} and CSL_{1B} are activated. In the example shown in FIG. 2 the activation of a column select line results the reading out four associated bit lines.

For repairing and/or replacing defective memory cells illustrated by “X”, or a rectangle filled in black in FIG. 2 the redundant columns are accessed. These are so called replacement column select lines CSL_{2A}, CSL_{3A}, CSL_{2B}, and CSL_{3B}. In the example shown in FIG. 2 a replacement column select line illustrates a group of four bit lines BL which are replaced together. This means that in this case always four bit lines are used simultaneously for repairing this defect, also if only one single defective memory cell is present.

In the memory architecture shown in FIG. 2 the repair is always carried out exclusively within the memory regions or the repair regions A and B. This is necessary because a normal column select line needs to be activated in each region for reading out eight data bits. A repair is therefore only possible within a repair region, as otherwise data conflicts would occur.

The disadvantage of the exemplary memory configuration described using FIG. 2 is that it comprises replacement column select lines which may only be used within one of the memory regions A and B, from which an inflexible, rigid construction results. A further disadvantage is that using the replacement column select lines only one repair may be carried out within one region. This is especially disadvantageous when the respective region comprises no or less defects than replacement column select lines, as in this case the remaining replacement structures and/or replacement column select lines may not be used for a repair in other regions, so that again this other disadvantage results that defective memory cells in other regions which would be replaceable due to the available overall number of replacement lines in the memory configuration may not be replaced due to the replacement lines associated with the individual regions. A further increase of efficiency due to the provision of redundant lines and/or redundant memory cells is therefore not possible due to the allocation of individual replacement structures to individual areas.

### SUMMARY OF THE INVENTION

It is the object of the present invention to provide an improved memory and an improved method for replacing defective memory cells in a memory, comprising a further increase of efficiency.

According to a first aspect, the present invention is a memory having a first memory region with at least one memory cell having an associated bit line, a second memory region having at least one memory cell with an associated bit line, a word line associated at least with the memory cell of the first memory region and the memory cell of the second memory region, at least one redundant memory cell having an associated bit line, and one means for selectively coupling the redundant memory cell to the bit line of the memory cell of the first memory region or to the bit line of the memory cell of the second memory region in order to replace a defective memory cell in the first memory region or a defective memory cell in the second memory region.

According to a second aspect, the present invention is a method for replacing defective memory cells in a memory including a first memory region having a memory cell with an associated bit line, a second memory region having a memory cell with an associated bit line, a word line at least associated with the memory cell of the first memory region and the memory cell of the second memory region, and at least one redundant memory cell having an associated bit line, wherein the method includes the step of selectively coupling the bit line of the redundant memory cell to the bit line of the memory cell of the first memory region or to the bit line of the memory cell of the second memory region in order to replace a defective memory cell in the first memory region or a defective memory cell in the second memory region.

According to the present invention a new approach is described to improve the efficiency in semiconductor memory devices due to the use of a modified line and/or column redundancy.

The present invention is based on the findings that an improvement of the efficiency in semiconductor memory devices by an enlargement of the above described repair regions and by a simultaneous repair in both regions may be achieved by same replacement structures.

According to a preferred embodiment of the present invention said memory includes a plurality of redundant memory cells and said memory regions in turn each include a plurality of redundant memory cells. The memory cells each comprise respectively associated bit lines. A predetermined number of the plurality of memory cells is combined in order to be read out simultaneously, wherein the activation of these combined memory cells is done by associated common activation lines, so-called column select lines. The coupling means is operative in this connection in order to selectively couple the bit lines of the combined memory cells to the bit lines of the combined memory cells of the first memory region or to the bit lines of the combined memory cells of the second memory region. The data of the respective regions are read out to corresponding local data buses and the data of the redundant memory cells are read out to an associated local data bus, and the coupling means selectively couples either the local data busses or the data bus associated with the redundant memory cells onto an output data bus or a global data bus.

According to a further preferred embodiment of the present invention wherein the memory configuration is such that a plurality of bit lines and associated memory cells are activated and read out via column select lines when activating the same, a repair using one single replacement column select line will be carried out for the case that two memory areas are activated simultaneously and for the case the two simultaneously activated column select lines comprise different bit lines comprising defective memory cells, wherein in a successive selection step the bit lines of the normal column select lines comprising functional memory cells and a replacement bit line of the associated replacement column select line are selectively switched onto the output for replacing the defective bit lines.

The advantage of this procedure is that hereby cell failures with future prefetch architectures wherein such cell failures occur increasingly with the same column address may be compensated for effectively as the probability that the defective memory cells are present on the same bit lines is very low.

### BRIEF DESCRIPTION OF THE DRAWINGS

In the following, preferred embodiments of the present invention are described in more detail referring to the accompanying drawings, in which:

FIG. 1 shows a schematic illustration of a first prior art memory configuration comprising several memory regions each having a redundant bit line associated with the same;

FIG. 2 shows a schematic illustration of a second prior art memory configuration comprising several memory regions that may be read out using column select lines and having memory regions associated with redundant column select lines;

FIG. 3 shows a schematic illustration of a first embodiment of a memory configuration according to the present invention;

FIG. 4 shows a schematic illustration of a second embodiment of a memory configuration according to the present invention; and

FIG. 5 shows a schematic illustration of an embodiment wherein individual bit lines of the replacement column select lines are coupled to bit lines of memory cells in the first memory region and to bit lines of memory cells in the second memory region in a configuration according to FIG. 4.

### DETAILED DESCRIPTION OF THE PREFERRED EMBODIMENTS

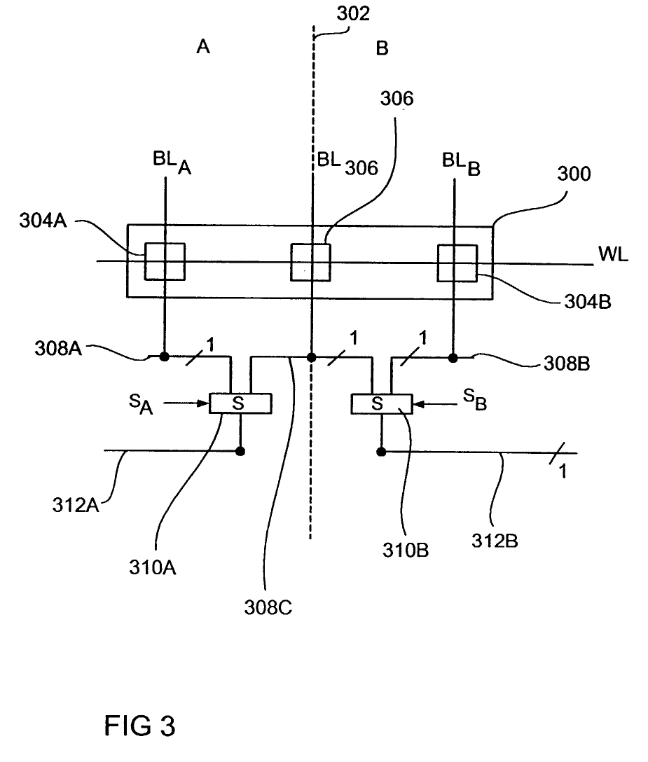

Referring to FIG. 3 a first embodiment of a memory configuration according to the present invention is explained in more detail in the following. In FIG. 3 a memory 300 is shown comprising a first memory region A and a second memory region B which are separated from another, as it is illustrated schematically by line 302.

The first memory region A includes a memory cell 302A which has a bit line BL_{A} associated with it.

The second memory region B includes a memory cell 304B which has a bit line BL_{B} associated with it.

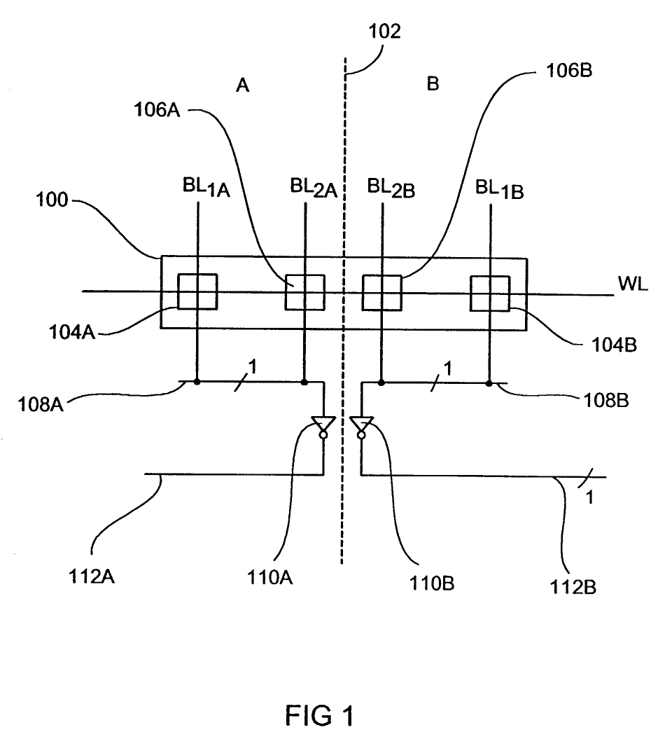

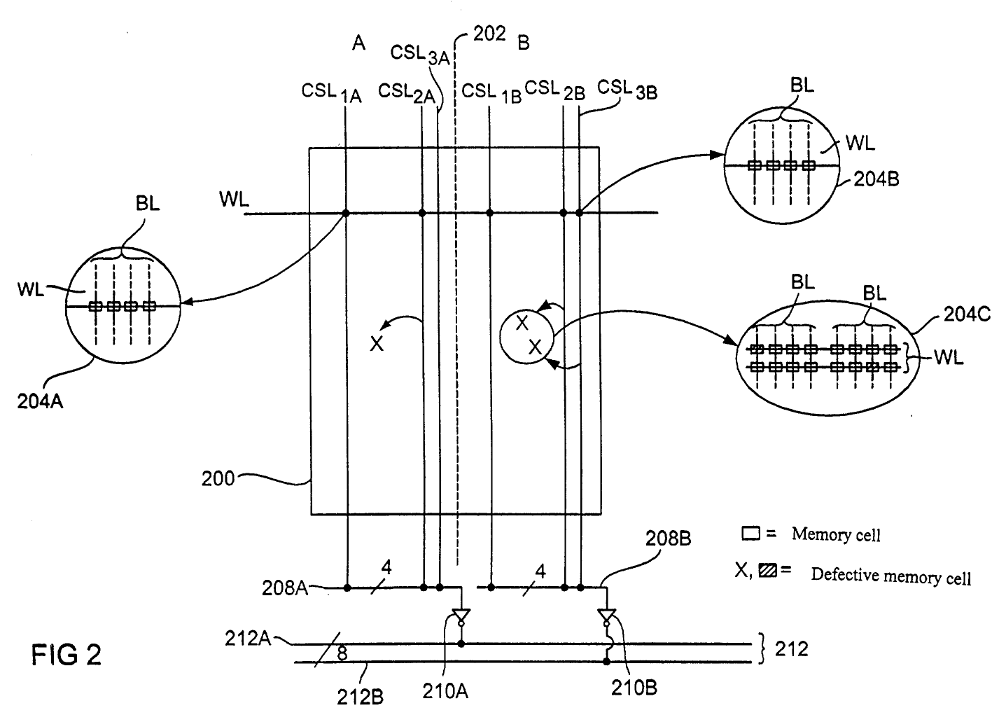

The memory 300 includes a redundant memory cell 306 which also has a bit line BL₃₀₆ associated with it. In contrast to the examples described according to FIGS. 1 and 2 no association of the redundant memory cell 306 to one of the memory regions A or B exists in the inventive memory configuration. Rather, the memory cell 306 is associated with both regions.

The memory 300 further includes a word line WL which is associated with the memory cells 304A, 304B and 306.

The bit line BL_{A} of the memory cell 304A is connected to a first local data bus 300A. As only one bit is read out of the memory cell 304A the width of the local data bus 308A is also only one bit, as it is shown in FIG. 3. The memory cell 304B is connected to a second local data bus 308B via the bit line BL_{B}. The redundant memory cell 306 is connected to a third local bus 308C via said bit line BL₃₀₆. The local buses 308B and 308C comprise a width of one bit like said bus 308A, as it is indicated.

The first local bus 308A and the third local bus 308C are connected to two inputs of the first change-over switch 310A, wherein its output is connected to a first global data bus and/or output data bus 312A. The second data bus 308B and the third data bus 308C are connected to the inputs of the second change-over switch 310B, wherein its output is connected to a second global data bus 312B. The first change-over switch 310A receives a signal SA at a control input and the second change-over switch 310B receives a signal S_{B} at a control input. As the regions A and B are accessed simultaneously in order to read out two bits, two output buses 312A and 312B are provided.

The functioning of the memory configuration as it is shown in FIG. 3 is such, that the region oriented association of the redundant memory cells according to the present invention is given up and the memory cell 306 is instead available as a replacement memory cell for both memory regions A and B.

In case none of the memory cells 304A and 304B is defective they are used normally, wherein in this case is it signalled to the change-over switches 310A and 310B via the control signals S_{A} and S_{B} that the data buses 308A and/or 308B are switched through to the global data bus 312A and/or 312B.

In case that for example one memory cell 304A is defective, it is replaced by the memory cell 306, and in this case the first change-over switch 310A is controlled via a respective control signal S_{A} in order to switch through the third data bus 308C onto the global data bus 312A instead of the first data bus 308A. The data bus 308B is further switched through to the global data bus 312B according to the applied control signal S_{B}.

The advantage of the present invention over the above described prior art is that here no fixed association of the replacement memory cell is given, so that a more flexible construction results. The redundant memory cell 306 may also be used to repair the memory cell 304A or 304B as the data may occur on both output data buses 312A or 312B through the inventive configuration.

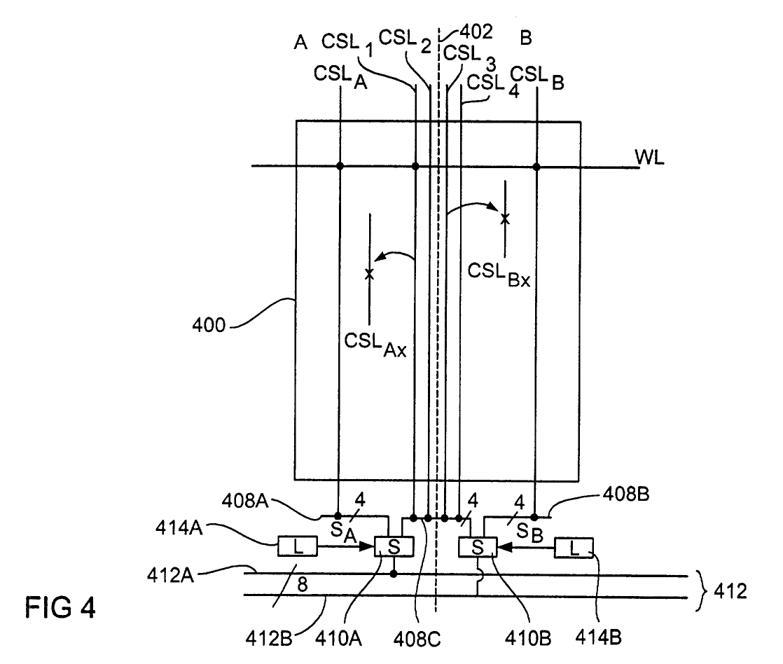

Referring to FIG. 4 a further preferred embodiment of the inventive memory configuration is described in more detail in the following, wherein the memory configuration in FIG. 4 is similar to the one described referring to FIG. 2 with regard to addressing individual bits, i.e. that by column select lines a predetermined number of memory cells and/or their associated bit lines are combined and at the same time activable, so that by activating a column select line for example two or more and preferably four bit lines are activated, so that at the output of a memory region four bits are applied when activating a line.

In FIG. 4 a memory configuration 400 is shown comprising a first memory region A and a memory region B separated from the same, as it is indicated by line 402. The memory region 400 includes a plurality of word lines WL, wherein for reasons of clarity only one word line WL is illustrated. The memory region A includes a plurality of column select lines, wherein for reasons of clarity only one column select line CSL_{A} is shown. Over the column select line CSL_{A} for example four bit lines are activated simultaneously at its activation, and in this regard reference is made to the description of FIG. 2 and in particular to portion 204A.

The memory region B also includes a plurality of column select lines, wherein also here only one column select line CSL_{B} is shown for reasons of clarity. The memory 400 further includes four replacement column select lines CSL₁, CSL₂, CSL₃, and CSL₄ in the illustrated embodiment. In contrast to the memory configuration described referring to FIG. 2 the allocation of the replacement column select lines with the individual memory regions A and B is eliminated in the embodiment shown in FIG. 4,: and the replacement column select lines CSL₁ to CSL₄ may be freely associated with each of the regions A and B. The association is done similar to the prior art, i.e. by replacing “normal” column select lines comprising bit lines with defective memory cells as it is indicated by the character “X” in FIG. 4 by said replacement column select lines. After the fixed association with the individual memory regions A and B is eliminated according to the present invention it needs to be ensured that no data conflicts occur when activating and/or reading out data.

In order to ensure this, the “normal” column select lines of the memory region A are associated with a first local data bus 408A as it is indicated by a connection of the column select line CSL_{A} to the first local data bus 408A. Additionally, the “normal” column select lines' of the second region B are associated with a second local data bus 408B. The replacement column select lines CSL₁ to CSL₄ are connected to a third local data bus 408C.

As four bit lines each are activated by the activation of a column select line in the illustrated embodiment, four bits are read out by said activation, so that the local data buses 408A, 408B, and 408C are four bits wide, as it is indicated.

The first local data bus 408A and the third local data bus 408C are connected to two inputs of the first change-over switch 410A, wherein its output is connected to a first portion 412A of a global data bus and/or a data output bus 412. The second data bus 408B and the third data bus 408C are connected to two inputs of the second change-over switch 410B, wherein its output is connected to a second portion 412B of the global data bus 412 in the embodiment shown in FIG. 4.

In the embodiment shown in FIG. 4 both memory regions A and B are activated simultaneously in order to thus read out four bit wide data words each from both regions in order to subsequently output an eight bit wide data word on the output data bus 412. Alternatively, the configuration may also be such that the memory regions A and B are not read out simultaneously and that only one four bit wide data word is output over the local data buses to the global data bus 412, wherein in this case the change-over switches 410A and 410B are connected to the same lines of the data bus 412.

The special thing about the architecture illustrated in FIG. 4 is that the additional third data bus 408C and the change-over switches 410A and 410B are provided, which may for example be formed by multiplexers. The third data bus 408C exclusively serves for routing data which are read out during an access over one of the replacement column select lines. The replacement column select lines of the two memory regions and/or repair regions A and B are combined and serve for repairing defective memory cells of the overall memory cell field 400, as it can be seen in FIG. 4. By this doubling of the size of the repair regions (compared to FIG. 2) the effectiveness, i.e. the repair of defective memory cells in field 400, may be increased.

The first data bus 408C, however, needs to replace one of the local data buses 408A or 408B when a redundancy case occurs, via the change-over switches 410A and 410B, for example the multiplexer or another logic circuit comprising a corresponding functionality. This is done by controlling via a so called fuse logic 414A and/or 414B, that provides the control signals S_{A} and/or S_{B}. In the fuse logic 414A, 414B the address and fuse information necessary for the redundancy case are processed.

If for example a defective memory cell occurs in the memory region A in the area of the region designated by “X”, the column select line associated with this memory cell will for example be replaced by the replacement column select line CSL₁. This replacement and the corresponding reprogramming is put into the fuse logic 414A, so that in the case that the defective column select line needs to be accessed the control signal S_{A} is provided via the logic circuit 414A in the first change-over switch 410A, which in this case switches the data bus 408C through to the first portion 412A and therefore outputs the bits onto the data output bus 412 read out by activating the replacement column select line CSL₁. Analogous a corresponding replacement of defective memory cells in the memory region B is carried out, wherein here the logic circuit 414B provides the corresponding control signal S_{B}.

In contrast to the approaches known in the art the present invention provides the advantage that due to summarising the redundant memory cells and/or replacement column memory cells a flexible construction is made possible for both memory regions A and B, which allows for a free use of the available redundant memory cells in the whole memory cell field 400, so that for example for the case that only one defect or no defect is present in the memory region A up to three and/or four defects may be corrected in the memory region B. Due to this flexible use of replacement column select lines the number of repaired memory cells may be increased, whereby in turn the efficiency increases.

One problem may, however, occur in the configuration illustrated in FIG. 4 when it is determined in a simultaneous addressing of the memory areas A and B for reading out the eight bit wide data words on-the output data bus 412 that a defect is present on two. simultaneously activated “normal” column select lines. This example is illustrated by the memory cells designated with “X” in FIG. 4, wherein one column select line with the same address “x” is associated with the same, as it is indicated by the reference numerals CSL_{AX} and CSL_{BX}. When reading out a data word from the memory field 400 the column select line CSL_{AX} in the memory region A and the column select line CSLBx in the memory region B may simultaneously be activated in this situation. By the concept described referring to FIG. 4 only one failure might be repaired in this case over the third data bus 308C, as during such an access the data bus 408C may either be connected to the data output bus 412 via the first change-over switch 410A or to the data bus 412 via the second change-over switch 410B.

Such a problem will be increased in future prefetch architectures, as here parallel data are massively read out with each applied address. In this case the probability of simultaneously occurring bits defects with the same memory address increases.

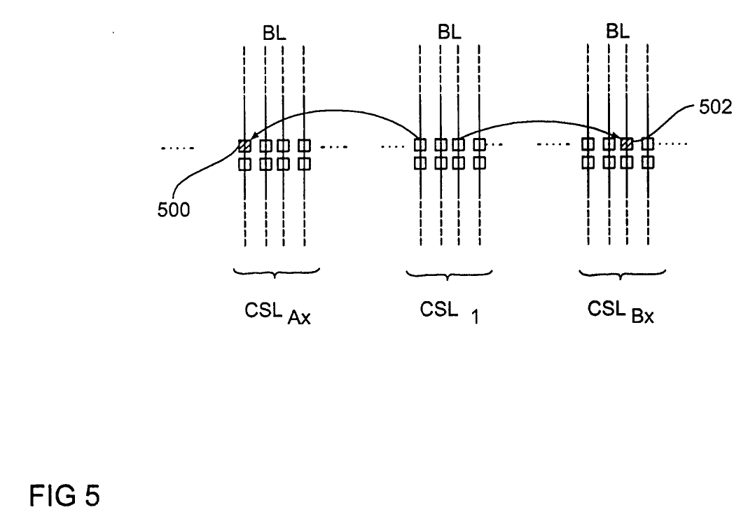

The inventive repair concept may however also be successfully implemented in the above described situations by generally refraining from advancing complete column select lines via said change-over switches and instead of that selectively redirecting the bit lines via the changeover switches which are associated with the individual normal column select lines and the individual replacement column select lines. This expansion of the functional concept of the present invention is explained in more detail referring to FIG. 5.

In FIG. 5 the above described situation as it was shown schematically in FIG. 4 is illustrated in an enlarged version and the column select lines CSL_{AX} and CSL_{BX} are illustrated enlarged. It is assumed that for Correcting the defective memory cells 500 and 502 the replacement column select line CSL₁ is used. As it can be seen from FIG. 5 it is to expected that the single bit errors 500 and 502 only coincide with the same bit line with a very low probability when replacing a cluster of about four bit lines each. In FIG. 5 it is shown that in the case of said column select line CSL_{AX} the defective memory cell is associated with the first bit line, wherein in the case of said column select line CSL_{BX} the defective memory cell 502 is associated with the third bit line. As it is schematically shown by the arrows the single errors 500 and 502 may simultaneously be repaired by one column select line CSL₁ in this example, which simply is accompanied by a provision of additional fuses and changing the fuse logic 414A, 414B (see FIG. 4), as now different bits of the data bus 408C need to be redirected simultaneously via the two multiplexes 410A and 410B onto the global data bus 412. In other words, no complete switching off of one of the two local data buses 408A and 408B is necessary in the redundancy case.

Regarding the embodiment illustrated referring to FIG. 5 the first change-over switch 410A is for example implemented such that it selects depending on the applied control signal S_{A} which of the bit lines of the normal column select lines CSL_{AX} and the replacement column select lines CSL₁ applied in the embodiment should be switched on to the four output lines of the first change-over switch 410A. The selection is carried out depending on the defective memory cells to be replaced and would lead to the second, the third and the fourth bit line of the normal column select line CSL_{AX} being redirected to the second, the third and the fourth output line of the change-over switch 410A in the embodiment illustrated in FIG. 5, and instead of the first bit line and the normal column select line CSL_{AX} containing the defective memory 510, the control signal S_{A} would cause the change-over switch to switch through the first bit line of the replacement column select line CSL₁ to the first bit line of the output lines of the change-over switch 410A. Accordingly, the change-over switch 410B would cause the first, the second and the fourth bit line of the normal column select line CSL_{BX} to be redirected to the first, the second and the fourth output line of the change-over switch 410B, and the third bit line of the replacement column select line CSL₁ being switched through to the third output line of the changeover switch 410B instead of the third bit line containing the defective memory cell 502.

With regard to the above described embodiments it is noted that the present invention is not restricted to the specific examples described therein, but that also other embodiments especially in combination with the memory configuration and the number of data bits to be read out simultaneously are possible. Instead of the described four bits also more or less bits may be read out simultaneously.

What is claimed is:

1. A memory, comprising
a first memory region having at least one memory cell with an associated bit line;
a second memory region having at least one memory cell with an associated bit line;
a word line at least associated with the memory cell of the first memory region and with the memory cell of the second memory region;
at least one redundant memory cell having one associated bit line; and
a means in order to selectively couple the bit line of the redundant memory cell to the bit line of the memory cell of the first memory region or to the bit line of the memory cell of the second memory region in order to replace a defective memory cell in the first memory region or a defective memory cell in the second memory region.

2. The memory according to claim 1 having a control means operatively connected to the coupling means in order to output a control signal to the coupling means controlling the coupling of the bit line of the redundant memory cells to one of the bit lines of the memory cells of the memory regions.

3. The memory according to claim 1, comprising
a first data bus associated with the bit line of the memory cell of the first memory region;
a second data bus associated with the bit line of the memory cell of the second memory region;
a third data bus associated with the bit line of the redundant memory cell; and
a fourth data bus that outputs data from the memory;
wherein the coupling means selectively couples the first data bus or the third data bus to the fourth data bus or selectively couples the second data bus or the third data bus to the fourth data bus.

4. The memory according to claim 3, wherein the coupling means comprises a first change-over switch and a second change-over switch,
wherein the first change-over switch includes two inputs connected to the first data bus and to the third data bus and an output connected to the fourth data bus,
wherein the second change-over switch includes two inputs connected to the second data bus and to the third data bus and an output connected to the fourth data bus,
wherein the first and the second change-over switch receive the control signal and connect the first or third data bus and/or the second or the third data bus to the fourth data bus depending on the signal.

5. The memory according to claim 4, wherein the control means includes a first logic circuit and a second logic circuit,
wherein the first logic circuit is associated with the first change-over switch and outputs a first control signal to the same;
wherein the second logic circuit is associated with the second change-over switch and outputs a second control signal to the same.

6. The memory according to claim 1, having a plurality of redundant memory cells with associated bit lines, wherein the first and the second memory region respectively include a plurality of memory cells with associated bit lines.

7. The memory according to claim 6, having a plurality of word lines associated with memory cells of the first memory region and the memory cells of the second memory region.

8. The memory according to claim 1, wherein the memory cells in the first memory region and the memory cells in the second memory region may be read out simultaneously, wherein data from the first memory region and data from the second memory region are combined to a common data word for an output from the memory.

9. The memory according to claim 8, wherein the fourth data bus comprises a first portion connected to the coupling means in order to receive data from the first data bus or from the third data bus, and wherein the fourth data bus comprises a second portion connected to the coupling means in order to receive data from the second data bus or from the third data bus.

10. The memory according to claim 9, wherein the output of the first change-over switch is connected to the first portion of the fourth data bus and wherein the output of the second change-over switch is connected to the second portion of the fourth data bus.

11. The memory according to claim 6, wherein a predetermined number of the plurality of memory cells of the first memory region are combined, wherein a predetermined number of the plurality of memory cells of the second memory region are combined, and wherein a predetermined number of the plurality of redundant memory cells are combined, wherein the combined memory cells are simultaneously activable for reading out data, wherein the coupling means selectively couples the bit lines of the combined redundant memory cells to the bit lines of the combined memory cells of the first memory region or to the bit lines of the combined memory cells of the second memory region.

12. The memory according to claim 11, wherein one common activation line is each associated with the combined memory cells.

13. The memory according to claim 11, wherein the coupling means is operative to selectively couple individual bit lines of the combined redundant memory cells individual bit lines of the combined memory cells of the first memory region and the second memory region.

14. A method for replacing defective memory cells in a memory including a first memory region having a memory cell with an associated bit line, a second memory region having a memory cell with an associated bit line, a word line at least associated with the memory cell of the first memory region and the memory cell of the second memory region, and at least one redundant memory cell having an associated bit line, wherein the method includes the following step:
selectively coupling the bit line of the redundant memory cell to the bit line of the memory cell of the first memory region or to the bit line of the memory cell of the second memory region in order to replace a defective memory cell in the first memory region or a defective memory cell in the second memory region.
